(19) United States
(12) Patent Application Publication
(10) Pub. No.: US 2023/0240051 A1
(43) Pub. Date: Jul. 27, 2023

(54) APPARATUS AND SYSTEM FOR HYBRID MULTI-PHASE SERVER COOLING

(71) Applicant: Baidu USA LLC, Sunnyvale, CA (US)

(72) Inventor: Tianyi GAO, San Jose, CA (US)

(21) Appl. No.: 17/583,641

(22) Filed: Jan. 25, 2022

(51) Int. Cl. H05K 7/20

(52) U.S. Cl. CPC H05K 7/20818; H05K 7/20836

(57) ABSTRACT

Embodiments are disclosed of an information technology (IT) cooling system. An IT container defines an internal volume and an immersion tank-which is adapted to submerge one or more servers in a two-phase immersion fluid and has a tank inlet fluidly coupled to a source of the two-phase immersion fluid. One or more cooling devices can be thermally coupled to a heat-generating component in a server, and each cooling device has a liquid inlet at or near its bottom and a vapor outlet at or near its top. A liquid distribution manifold below the cooling devices has a main liquid inlet and a plurality of liquid distribution outlets; at least one liquid distribution outlet is fluidly coupled to the liquid inlet of a cooling device. A vapor return above the one or more cooling devices has a plurality of vapor collection inlets and a main vapor outlet. At least one vapor collection inlet is fluidly coupled to the vapor outlet of a cooling device, so that a second two-phase fluid circulates through the liquid distribution manifold, the cooling devices, and the vapor return manifold.

### TECHNICAL FIELD

The disclosed embodiments relate generally to two-phase information technology (IT) cooling systems, but not exclusively, to an apparatus and system for hybrid multi-phase server cooling.

### BACKGROUND

Modern data centers like cloud computing centers house enormous amounts of information technology (IT) equipment such as servers, blade servers, routers, edge servers, power supply units (PSUs), battery backup units (BBUs), etc. These individual pieces of IT equipment are typically housed in racks within the computing center, with multiple pieces of IT equipment in each rack. The racks are typically grouped into clusters within the data center.

As IT equipment has become more computationally powerful it also consumes more electricity and generates more heat that must be removed from the IT equipment to keep it operating properly. Various cooling solutions have been developed to keep up with this increasing need for heat removal. One solution is immersion cooling, in which the IT equipment is itself submerged in an immersion cooling fluid. The immersion cooling fluid can be a single-phase or two-phase cooling fluid; in either case, heat from the IT equipment is transferred into the cooling fluid in which it is submerged. But existing two-phase immersion solutions have all the servers submerged in the IT enclosure, so that vapor is generated and condensed within the IT enclosure. This solution does not handle the high power density and vapor efficiently, as a result of which current two-phase immersion cooling solutions do not sufficiently support high power density servers. Such two-phase designs are also inefficient and may not be a good solution for hyperscale deployment.

### BRIEF DESCRIPTION OF THE DRAWINGS

Non-limiting and non-exhaustive embodiments of the present invention are described with reference to the following figures, wherein like reference numerals refer to like parts throughout the various views unless otherwise specified.

FIGS. 1A-1B are schematic views of an embodiment of an information technology (IT) enclosure including cooling components. FIG. 1A is a side view, FIG. 1B a front view.

FIG. 2 is a schematic view of an embodiment of a two-phase circulation cooling loop of an IT cooling system.

FIG. 3 is a schematic front view of another embodiment of an information technology (IT) enclosure including cooling components.

FIG. 4 is a schematic front view of another embodiment of an information technology (IT) enclosure including cooling components.

FIG. 5 is a schematic front view of another embodiment of an information technology (IT) enclosure including cooling components.

### DETAILED DESCRIPTION

Embodiments are described of hybrid multi-phase server cooling systems for use with information technology (IT) equipment in a data center or an IT container such as an IT rack. Specific details are described to provide an understanding of the embodiments, but one skilled in the relevant art will recognize that the invention can be practiced without one or more of the described details or with other methods, components, materials, etc. In some instances, well-known structures, materials, or operations are not shown or described in detail but are nonetheless encompassed within the scope of the invention.

Reference throughout this specification to “one embodiment” or “an embodiment” means that a described feature, structure, or characteristic can be included in at least one described embodiment, so that appearances of “in one embodiment” or “in an embodiment” do not necessarily all refer to the same embodiment. Furthermore, the particular features, structures, or characteristics may be combined in any suitable manner in one or more embodiments. As used in this application, directional terms such as “front,” “rear,” “top,” “bottom,” “side,” “lateral,” “longitudinal,” etc., refer to the orientations of embodiments as they are presented in the drawings, but any directional term should not be interpreted to imply or require a particular orientation of the described embodiments when in actual use.

The disclosed embodiments are systems for two-phase cooling of IT components. The disclosed embodiments use a two-phase fluid recirculation and management system for thermal management using two-phase coolants to solve high power density applications and corresponding challenges associated with two-phase immersion cooling technologies. In addition, the disclosed embodiments enable some or all of the following benefits:
Solve hot spot issues associated with two-phase immersion cooling.
Increased cooling and power usage efficiency.
Vapor management efficiency.
Better thermal management of high power density chips.
Accommodate different server hardware, electronics, and configurations.
Localized precision cooling design and management.
Ease of deployment, operation, and service.
Expandable for future power and density increases.

The described embodiments are of a system with advanced two-phase coolant management for effective handling of high power-density cooling and efficient vapor management. The described embodiments include a first two-phase vapor system which is used for directly supplying a two-phase immersion coolant to an IT container. The servers are fully submerged within the two-phase immersion coolant and are also thermally coupled to cooling devices that circulate a two-phase circulation coolant. The cooling devices are fluidly coupled by connectors to a bottom distribution unit and a top vapor manifold. The core of each cooling device is used to contain the two-phase circulation coolant, and each cooling device is connected to the vapor manifold with a vapor line. The two-phase circulation coolant is used for high power density spots and the core of the cooling module is being filled with the two-phase coolant through the bottom distribution unit in which the two-phase coolant is in high pressure. In an embodiment, the two-phase immersion coolant and the two-phase circulation coolant are the same two-phase fluid.

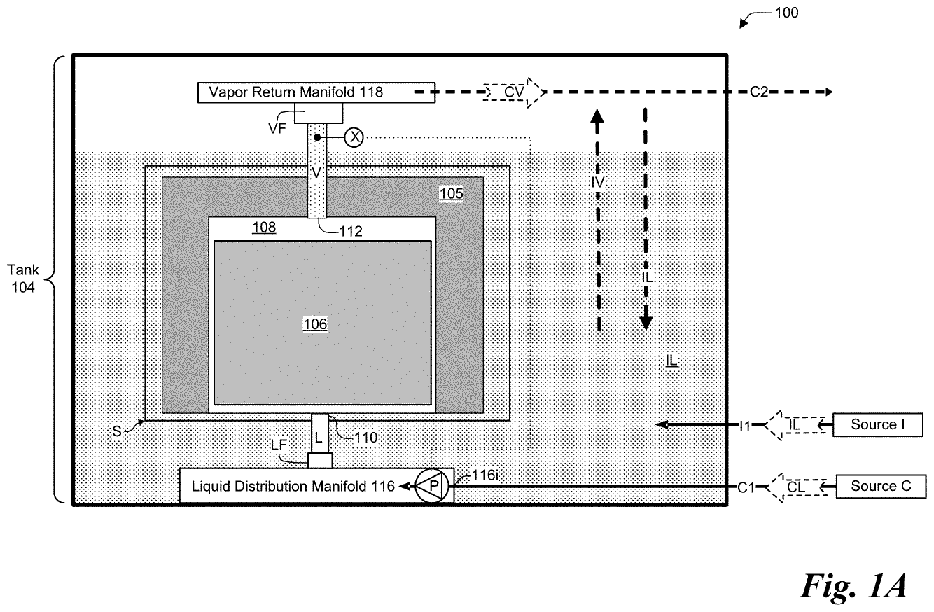

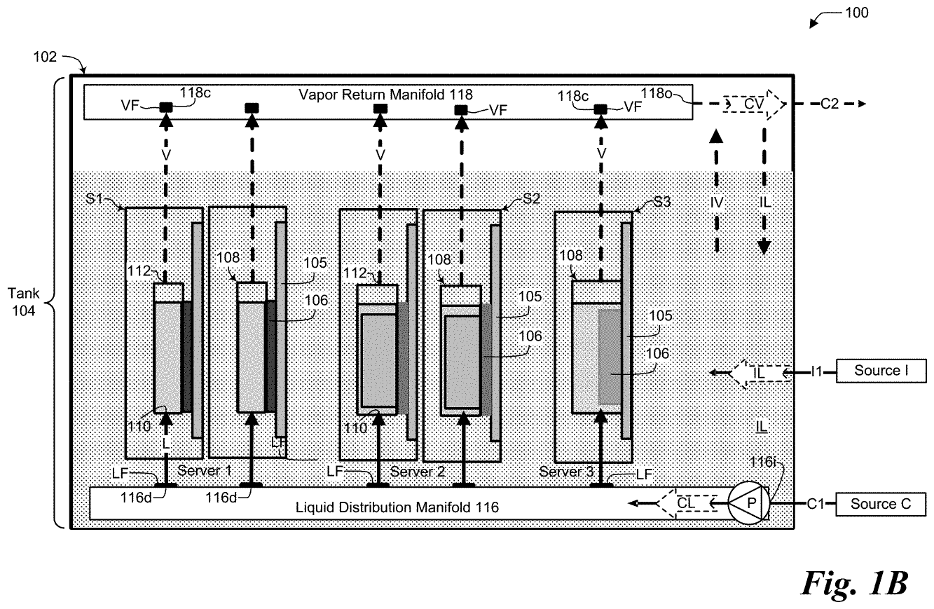

FIGS. 1A-1B together illustrate an embodiment of an information technology (IT) cooling system 100; FIG. 1A is a side view, FIG. 1B a front view. Cooling system 100 combines immersion cooling with local fluid circulation to cool heat-generating electronics components. Immersion cooling is accomplished with a two-phase immersion fluid I having a liquid phase IL and a vapor phase IV, while circulation cooling is accomplished with a two-phase circulation fluid C having a liquid phase CL and a vapor phase CV. In most embodiments immersion cooling fluid I will be a dielectric fluid, meaning that it has little or no electrical conductivity. In one embodiment immersion cooling fluid I and circulation cooling fluid C are the same two-phase fluid, but in other embodiments immersion cooling fluid I and circulation cooling fluid C can be different two-phase fluids; depending on the application, in embodiments where they are different fluids immersion cooling fluid I and circulation cooling fluid C can have different boiling points. In an embodiment where circulation fluid C must extract more heat than immersion fluid I, circulation fluid C will have a lower boiling point, enabling it to absorb and transfer away more heat. The system is designed to minimize or prevent mixing of the immersion (I) and circulation (C) fluids, but in embodiments where the two fluids are the same some mixing can be permissible.

Cooling system 100 includes an information technology (IT) container 102 that defines an internal volume. An immersion tank 104 in the internal volume is adapted to hold the liquid phase IL of two-phase immersion cooling fluid I. In the illustrated embodiment the internal volume of IT container 102 forms immersion tank 104 and the lower part of immersion tank 104 is used to hold liquid phase IL, but in other embodiments immersion tank 104 can be a physically separate tank within IT container 102. IT container 102 is sealed to reduce or prevent escape of liquid phase IL and, during operation, escape of vapor phase IV. Immersion tank 104 can be understood as the immersion fluid region in this design—that is, the region in which servers are immersed and submerged in two-phase immersion fluid I for cooling, as further described below. To allow the liquid level within tank 104 to be maintained, the immersion tank is fluidly coupled via a liquid line I1 to a source I of the two-phase immersion fluid.

In the illustrated embodiment, one or more servers S are within the IT container 102. The illustrated embodiment includes multiple servers S1, multiple servers S2, and a single server S3, but other embodiments can have a different total number of servers than shown and a different number of each server type than shown, including none of a particular type. Within each server S there are one or more heat-generating electronic components 106 mounted on a circuit board 105. Cooling device 108, which can be an evaporator in one embodiment, has a liquid inlet 110 and a vapor outlet 112. Servers S are submerged in liquid phase IL, and to ensure proper immersion cooling of the servers the amount or level of liquid phase IL in immersion tank 104 is set so that the one or more servers S always remain fully submerged in the liquid phase.

A cooling device 108 is thermally coupled to the heat-generating electronic component in at least one server. Each cooling device includes a compartment for containing a volume of two-phase circulation fluid to extract the heat from the heat-generating component. In the illustrated embodiment the primary difference between servers S1, S2, and S3 is the construction of cooling device 108. In servers S1, cooling device 108 is a self-contained cooling device with a thermal contact surface that is thermally coupled to a surface of heat-generating component 106, so that the circulation fluid flowing through the cooling device is kept separate from the heat-generating device. In servers S2 cooling device 108 is coupled to a surface of heat-generating component 106, so that circulation fluid flowing through the cooling device is in direct thermal contact with the entire heat-generating device. Finally, in server S3 cooling device 108 is mounted to circuit board 105 in such a way that the heat-generating component 106 is completely immersed within the circulation fluid flowing through cooling device 108. In the illustrated embodiment boards 105 are positioned vertically, so that for each cooling device 108 the liquid inlet 110 is at or near the bottom and vapor outlet 112 is at or near the top. Other embodiments need not position boards 105 vertically, but it is desirable for the vapor outlet to be above the liquid inlet. In some embodiments, each liquid inlet 110 can include a bottom connector such as a blind mating connector that allows each liquid inlet 110 one to be mated with the liquid fittings LF on the liquid distribution manifold. Similarly, in some embodiments each vapor outlet 112 can include a connector such as a manual quick disconnect connector that allows each vapor outlet 112 to be mated with the vapor fittings VF with the vapor return manifold.

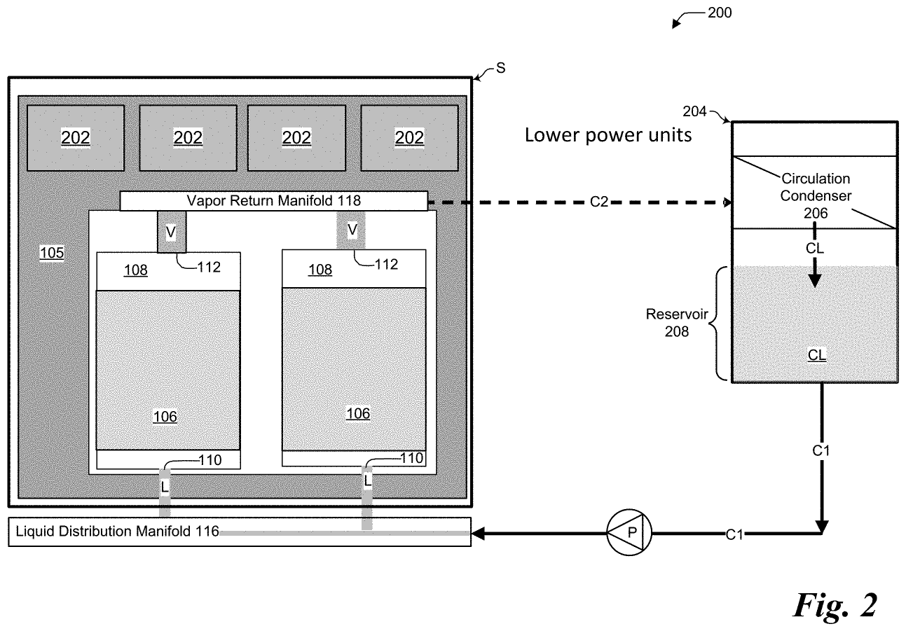

Besides immersion tank 104 and cooling devices 108, two main cooling components are positioned in the interior volume of IT container 102: a liquid distribution manifold 116 and a vapor return manifold 118. As described below, cooling device 108, liquid distribution manifold 116, and vapor return manifold 118 form part of a two-phase circulation cooling loop to provide localized two-phase cooling to heat-generating component 106. Liquid distribution manifold 116 includes a main inlet 116i and multiple liquid distribution outlets 116d. Each liquid distribution outlet 116d includes a liquid fitting LF that allows the liquid distribution outlet to be fluidly coupled, via a liquid line L, to the liquid inlet 110 of a corresponding cooling device 108. In one embodiment liquid fittings LF can be quick-disconnect blind mating connectors, but in other embodiments they can be other types of fluid connectors. In still other embodiments, liquid fittings LF need not all be the same kind of fitting. To circulate fluid through the circulation cooling loop formed by liquid distribution manifold 116, cooling devices 108, and vapor return manifold 118, both liquid distribution manifold 116 and vapor return manifold 118 include fluid connections that allow them to be fluidly coupled to external components (i.e., components outside IT container 102). In the illustrated embodiment, liquid distribution manifold 116 includes a liquid connection C1 fluidly coupled between main inlet 116i and a source C of the two-phase circulation fluid. A main pump P is coupled into fluid line C1 to boost the pressure, and hence the flow rate, of two-phase circulation fluid in liquid distribution manifold 116. In the illustrated embodiment, main pump P is positioned within liquid distribution manifold 116 downstream of the main inlet 116i, but in other embodiments main pump P can be positioned differently, for instance outside liquid distribution manifold 116 or outside IT container 102 (see, e.g., FIG. 2).

Vapor return manifold 118 includes a main vapor outlet 118o and multiple vapor collection inlets 118c. Each vapor collection inlet 118c includes a vapor fitting VF that allows the vapor collection inlet to be fluidly coupled through a vapor line V to the vapor outlet 112 of a corresponding cooling device 108. In one embodiment vapor fittings VF can be manual quickdisconnect connectors, but in other embodiments they can be other types of fluid connectors and in any given embodiment vapor fittings LF need not all be the same kind of vapor fitting. Vapor return manifold 118 includes a vapor line C2 fluidly coupled between main vapor outlet 118o and a condenser (not shown in this figure, but see FIG. 2). The illustrated embodiment also includes a liquid sensor X positioned in vapor line V (see FIG. 1A). Liquid sensor X is communicatively coupled to main pump P, so that the speed of main pump P can be controlled based on whether sensor X detect the presence of liquid in a vapor line. Generally, it is desirable to have only vapor, and no liquid, flowing through each vapor line V. If liquid is detected in a vapor line V, it signals that the liquid entering each cooling device 108 is not evaporating quickly enough. In response, the main pump P can be slow so that the less liquid enters the cooling device and the liquid that does enter is fully evaporated. In some embodiments, liquid may flow through a vapor line V when the pump speed is high in ways that may not impact normal system operation.

During operation of cooling system 100, heat-generating components 106 within servers S are cooled by two cooling loops: an immersion cooling loop and a circulation cooling loop. In the immersion cooling loop, heat generated by heat-generating components 106 is transferred to liquid phase IL of the immersion fluid I, transforming it by evaporation into vapor phase IV. Vapor phase IV rises into the space between a surface of the liquid phase IL in immersion tank 104 and the top of IT container 202, where it condenses back into liquid phase IL. Under the force of gravity, liquid phase IL returns to immersion tank 104, where it will again be transformed by heat from components 106 into vapor phase IV, thus completing the immersion cooling loop.

The circulation cooling loop operates simultaneously with the immersion cooling loop to provide enhanced and more localized cooling to heat-generating components 106. The liquid phase CL of circulation cooling fluid C flows through liquid line C1 into main inlet 116i, through main pump P, and through liquid distribution manifold 116. From the liquid distribution manifold, the liquid phase flows through liquid supply lines L and liquid inlets 110 into cooling devices 108, where liquid phase CL absorbs heat from heat-generating devices 106 and is converted into vapor phase CV. Vapor phase CV then flows out of cooling devices 108 through vapor outlets 112 and vapor lines V to vapor return manifold 118. Vapor phase CV then flows out of vapor return manifold 118 through vapor line C2.

FIG. 2 illustrates an embodiment of a circulation cooling loop 200 that can be used in cooling system 100. FIG. 2 should be understood as a schematic representation, not an actual hardware design diagram, so that the illustrated elements need not be built or arranged exactly as depicted. For instance, although vapor return manifold 118 is shown in the figure as an element separate from IT container 102, in some embodiments the vapor return manifold can be designed on, or integrated with, the IT container. Circulation loop 200 includes additional components besides those shown in system 100, principally condenser unit 204, that help to circulate the two-phase circulation fluid through the loop.

Cooling loop 200 includes substantially the same cooling components coupled to each server S as shown in system 100. Each server S includes one or more heat-generating electronic components 106 mounted on a circuit board 105, and a cooling device 108 is thermally coupled to each heat-generating electronic component 106. Each cooling device 108, which can be an evaporator in one embodiment, has a liquid inlet 110 and a vapor outlet 112. Although not illustrated in this particular drawing, server S is submerged in liquid phase IL, as shown for system 100. Low-power components 202—e.g., components that do not need additional cooling beyond what is provided by immersion cooling—can be positioned at the top of circuit board 105, above the vapor return manifold.

Liquid distribution manifold 116 and a vapor return manifold 118 are fluidly coupled to cooling devices 108. Liquid distribution outlets in manifold 116 are fluidly coupled by liquid lines L to liquid inlets 110, and vapor collection inlets in vapor return manifold 118 are fluidly coupled by vapor lines V to vapor outlets 112, as described above. To circulate the two-phase circulation fluid C through cooling loop 200, liquid distribution manifold 116 includes a liquid line C1 fluidly coupled between main inlet 116i and condenser unit 204.

Cooling loop 200 includes two primary components that are fluidly coupled to liquid distribution manifold 116 and vapor return manifold 118 to assist them in performing their functions: a condenser unit 204 and a pump P. Condenser unit 204 includes a circulation condenser 206 fluidly coupled to a liquid reservoir 208. Circulation condenser 206 is fluidly coupled by vapor return line C2 to vapor return manifold 118, and also is fluidly coupled to liquid reservoir 208. Liquid distribution manifold 116 is fluidly coupled by liquid line C1 and main pump P to liquid reservoir 208; in this embodiment, then, reservoir 208 is equivalent to source C of system 100. But unlike system 100, in cooling loop 200 main pump P is positioned outside the liquid distribution manifold; in different embodiments, main pump P can be inside or outside IT container 102. In this loop arrangement, then, liquid phase CL flows through liquid line C1 and vapor phase CV flows through vapor line C2. Main pump P is fluidly coupled into liquid supply line C1 to boost the pressure and/or flow rate of liquid phase CL flowing into and through liquid distribution manifold 116.

Cooling loop 200 operates substantially as described above for the circulation loop in system 100. Vapor phase CV flows out of cooling device 108 through vapor outlet 112 and vapor line V to vapor return manifold 118. Vapor phase CV then flows through vapor line C2 from vapor return manifold 118 to circulation condenser 206. In circulation condenser 206 vapor phase CV is transformed into liquid phase CL. Under the influence of gravity, liquid phase CL is delivered from circulation condenser 206 to liquid reservoir 208. Liquid phase CL is then returned to liquid distribution manifold 116 through liquid line C1 with the assistance of main pump P, thus completing the circulation cooling loop. Circulation loop 200 is typically the main cooling system because it functions as a localized high power density thermal management system in a fully two-phase immersion environment.

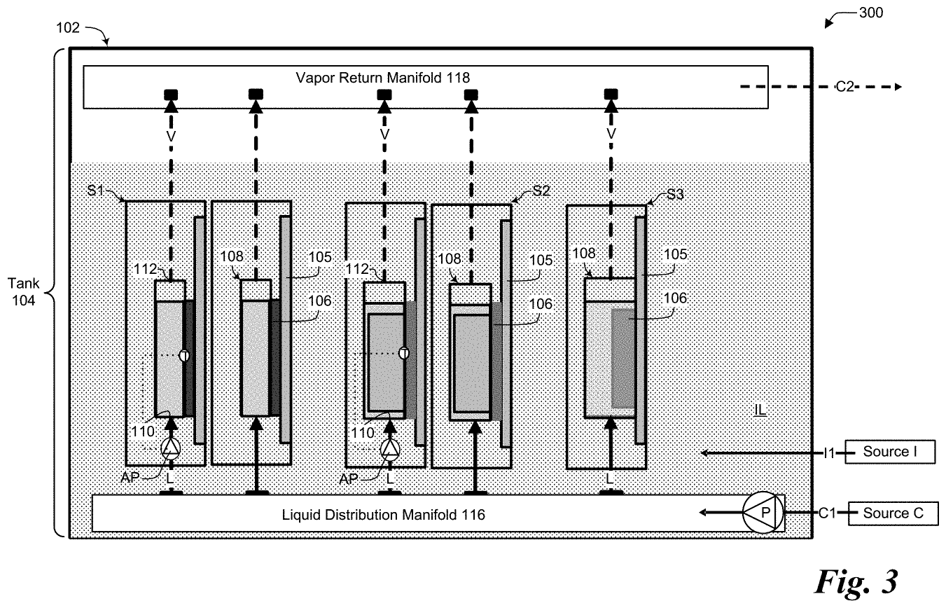

FIG. 3 illustrates another embodiment of a two-phase cooling system 300. System 300 is in most ways similar to system 100 shown in FIGS. 1A-1B; it includes the same components coupled to each other in substantially the same way. The primary difference between systems 100 and 300 is that system 300 includes additional fluid and control components to manage operation of the system. System 300, then, operates similarly to system 100, but with additional controls.

In addition to the components of system 100, system 300 includes an auxiliary pump AP in one or more of the liquid lines L that fluidly couple liquid distribution manifold 116 to the liquid inlets 110 of cooling devices 108. For cooling devices 108 whose liquid inlet 110 is coupled to an auxiliary pump, a temperature sensor T is positioned on heat-generating component 106 to measure its temperature or is positioned within cooling device 108 to measure the liquid or vapor temperature within the cooling device. Each temperature sensor T is communicatively coupled to its corresponding auxiliary pump AP, so that the auxiliary pump can be controlled based on the temperature sensor's output. For instance, if temperature sensor T detects a temperature that is too high it can increase the speed of its corresponding auxiliary pump AP. The increased pump speed increases the pressure and flow rate of liquid entering the cooling device, thus reducing the temperature. Conversely, if temperature sensor T detects a temperature that is too low it can decrease the speed of its corresponding auxiliary pump AP. The decreased pump speed decreases the pressure and flow rate of liquid entering the cooling device, thus increasing the temperature.

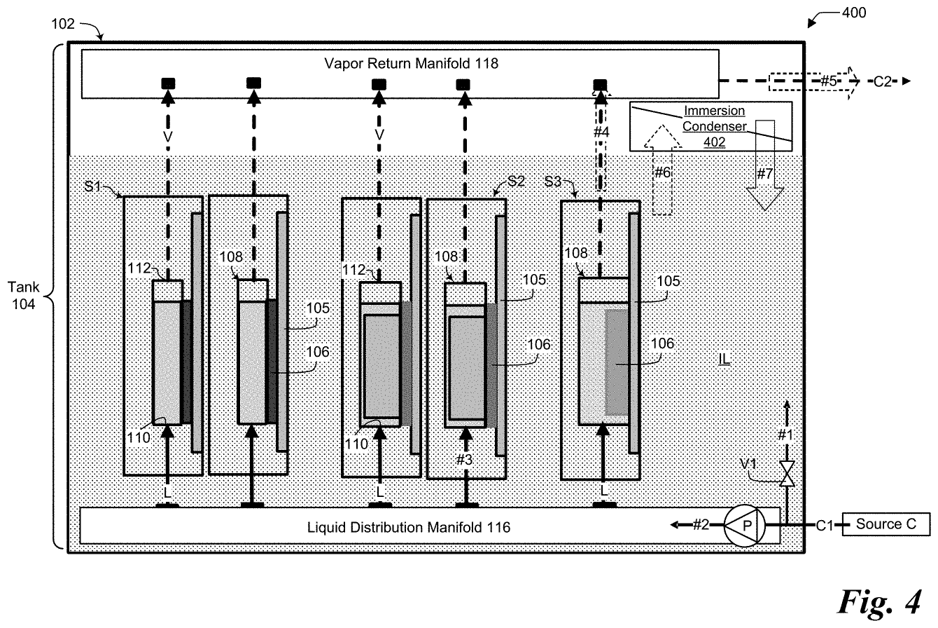

FIG. 4 illustrates another embodiment of a two-phase cooling system 400. Cooling system 400 is in most respects similar to cooling system 100. System 400 includes IT container 102 and the same components within IT container 102 fluidly connected in the same way. The primary difference between systems 100 and 400 is that system 400 includes additional cooling and control components to manage operation of the system. System 400, then, operates similarly to system 100, but with additional controls and cooling components.

To assist cooling in the immersion cooling loop, system 400 includes an immersion condenser 402 positioned above tank 104 within IT enclosure 102. Immersion condenser 402 serves to condense the two-phase immersion cooling fluid I from its vapor phase IV to its liquid phase IL. In the illustrated embodiment, immersion condenser 402 is not coupled by physical fluid connections to other components within IT container 102, but another embodiment that could be fluidly coupled to other components, such as a cooler, to improve its performance. In addition to immersion condenser 402, system 400 includes a control valve V1 that is positioned within IT container 102 and is fluidly coupled in liquid line C1 upstream of liquid distribution manifold 116. Control valve V1 can be opened and closed to control the flow of liquid from liquid line C1 into immersion tank 104: when control valve V1 is open, its outlet delivers liquid phase IL of two-phase immersion cooling fluid I into tank 104. Thus, control valve V1 can be used to control replenishment of the liquid phase IL in tank 104. Because liquid phase IL comes from liquid line C1, in this embodiment the two-phase immersion fluid I and the two-phase circulation fluid C are the same two-phase fluid. As a result, fluid sources I and C from system 100 (see FIG. 1B) can be merged into a single source or, alternatively one of fluid sources I or C can be eliminated altogether.

In operation of system 400, the immersion cooling loop and the circulation cooling loop operate simultaneously as described above for system 100. In the immersion cooling loop, vapor phase IV rises into the space between a surface of the liquid phase IL in immersion tank 104 and the top of IT container 202, where it enters immersion condenser 402 and condenses back into liquid phase IL. Under the force of gravity, liquid phase IL drops from immersion condenser 402 back into immersion tank 104, where it will again be transformed by heat from component into vapor phase IV, thus completing the immersion cooling loop. In this embodiment, then, vapor generated by heat-generating components 106 and by components such as low-power units 202 (see FIG. 2), if present, is fully contained in the IT enclosure and is separate from the vapor in the circulation loop and cooling devices 108.

As in system 100, in system 400 the circulation cooling loop operates simultaneously with the immersion cooling loop. The liquid phase CL of circulation cooling fluid C flows through main pump P into liquid distribution manifold 116. From the liquid distribution manifold the liquid phase flows through liquid supply line L and liquid inlet 110 into cooling device 108, where the liquid phase CL absorbs heat from heat-generating device 106 and is converted into vapor phase CV. Vapor phase CV then flows out of cooling device 108 through vapor outlet 112 and vapor line V to vapor return manifold 118. Vapor phase CV then flows out of vapor return manifold 118 through vapor line C2.

The fluid paths of system 400 described above are represented in the figure by the arrows labeled #1 through #7 as follows:

#1: main supply of the liquid phase IL of two-phase immersion cooling fluid I into immersion tank 104 (note that in this embodiment both two-phase cooling fluids are the same, so that IL and CL are liquid phases of the same fluid).

#2: main supply of the liquid phase CL of two-phase circulation cooling fluid C into liquid distribution manifold 116.

#3: flow of liquid phase CL through liquid line L and into cooling device 108 through liquid inlet 110.

#4: flow of vapor phase CV of the two-phase circulation coolant through vapor line V from the vapor outlet 112 of cooling device 108 and into vapor return manifold 118.

#5: flow of vapor phase CV through vapor line C2 from the vapor return manifold 118 to the exterior of IT enclosure 102.

#6: generation of vapor phase IV of two-phase immersion cooling fluid I and its rise from tank 104 to immersion condenser 402.

#7: return of liquid phase IL from immersion condenser 402 to tank 104.

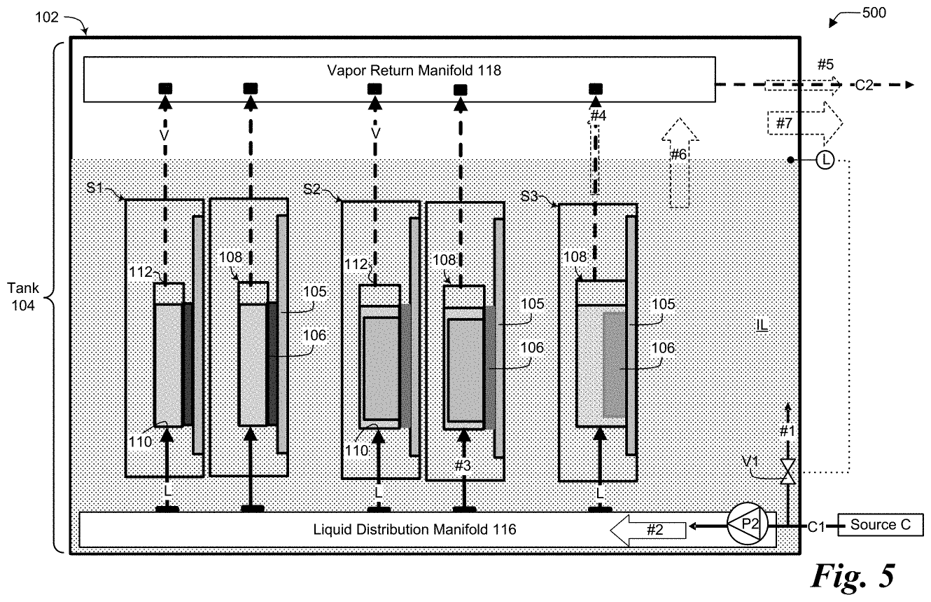

FIG. 5 illustrates another embodiment of a two-phase cooling system 500. Cooling system 500 is in most respects similar to cooling system 400; system 500 includes IT container 102 and most of the same components within IT container 102, and they are fluidly coupled in the same way. The primary difference between systems 500 and 400 is that system 500 includes additional fluid and control components to manage operation of the system, but excludes an immersion condenser and therefore has different fluid paths. System 500, then, operates similarly to system 400, but with additional or different controls and different fluid paths.

IT container 102 cannot be perfectly sealed against exit of vapor phase IV, so the amount of liquid phase IL in immersion tank 104 naturally decreases over time and must occasionally be replenished so that the one or more servers S are always kept fully submerged in the liquid phase IL of the immersion fluid. To monitor the need for replenishment, a liquid level sensor L is positioned in immersion tank 104 and is communicatively coupled to control valve V1. Control valve V1 is in turn fluidly coupled to liquid line C1. As in system 400, in system 500 liquid phase IL comes from liquid line C1, meaning that the two-phase immersion fluid I and the two-phase circulation fluid C are the same two-phase fluid; as a result, fluid sources I and C from system 100 (see FIG. 1B) can be merged into a single source or, alternatively one of fluid sources I or C can be eliminated altogether.

Liquid level sensor L is positioned in immersion tank 104 and can be used to control the open ratio of valve V, thus controlling the level of liquid phase IL in the tank. The open ratio of control valve V1 is a measure of how open the valve is. In one embodiment the open ratio can have any value between 0 and 1: an open ratio of 0 means the valve is fully closed and all flow is cut off; an open ratio of 1 means the valve is fully open and fluid flows freely through it; an open ratio of 0.5 means the valve is half open; and so on. If the level of liquid IL in immersion tank 104 drops below the required level, the open ratio of control valve V1 is increased, allowing liquid IL to flow into immersion tank 104 until the require liquid level is restored. Once the required liquid level is restored, the open ratio of control valve V1 is decreased to slow or stop the flow of liquid IL into the tank.

In operation of system 500, the immersion cooling loop and the circulation cooling loop operate simultaneously as described above for system 400. In the immersion cooling loop, vapor phase IV rises into the space between a surface of the liquid phase IL in immersion tank 104 and the top of IT container 202, and then exits IT container 102. To make up for the loss of fluid cause by vapor exiting the IT enclosure, the liquid phase IL of the immersion fluid flows into immersion tank 104 through control valve V1 under the direction of liquid level sensor L; liquid level sensor L monitors the level of liquid L in immersion tank 104 and opens and closes control valve V1 as necessary to maintain the proper level of liquid in the tank.

In system 500 the circulation cooling loop operates simultaneously with the immersion cooling loop to provide enhanced and more localized cooling to heat-generating components 106. The liquid phase CL of circulation cooling fluid C flows through main pump P into liquid distribution manifold 116. From the liquid distribution manifold the liquid phase flows through liquid supply line L and liquid inlet 110 into cooling device 108, where the liquid phase CL absorbs heat from heat-generating device 106 and is converted into vapor phase CV. Vapor phase CV then flows out of cooling device 108 through vapor outlet 112 and vapor line V to vapor return manifold 118. Vapor phase CV then flows out of vapor return manifold 118 through vapor line C2.

The fluid paths of system 500 described above are represented in the figure by the arrows labeled #1 through #7:

#1: main supply of the liquid phase IL of two-phase immersion cooling fluid I into immersion tank 104 (note that in this embodiment both two-phase cooling fluids are the same, so that IL and CL are liquid phases of the same fluid).

#2: main supply of the liquid phase CL of two-phase circulation cooling fluid C into liquid distribution manifold 116.

#3: flow of liquid phase CL through liquid line L and into cooling device 108 through liquid inlet 110.

#4: flow of vapor phase CV of the two-phase circulation coolant through vapor line V from the vapor outlet 112 of cooling device 108 and into vapor return manifold 118.

#5: flow of vapor phase CV through vapor line C2 from the vapor return manifold 118 to the exterior of IT enclosure 102.

#6: generation of vapor phase IV of two-phase immersion cooling fluid I and its rise from tank 104 to immersion condenser 402.

#7: exit of vapor phase IV from IT container 102.

Other embodiments are possible besides the ones described above. For instance:

The servers can be designed in different configurations.

The cooling module can be designed differently to accommodate different servers and electronics.

The IT enclosure can be designed differently for different servers.

The above description of embodiments is not intended to be exhaustive or to limit the invention to the described forms. Specific embodiments of, and examples for, the invention are described herein for illustrative purposes, but various modifications are possible.

What is claimed is:

1. An information technology (IT) equipment cooling system, the system comprising:
an IT container defining an internal volume, the internal volume having therein:
an immersion tank adapted to submerge one or more servers in a two-phase immersion fluid,
one or more cooling devices, each cooling device designed to contain a volume of two-phase circulation fluid and adapted to be thermally coupled to a heat-generating component in one of the one or more servers and each cooling device including a liquid inlet and a vapor outlet,
a liquid distribution manifold positioned below the one or more cooling devices, the liquid distribution manifold fluidly coupled by a liquid line to the liquid inlet of each of the one or more cooling devices, and
a vapor return manifold positioned above the one or more cooling devices, the vapor return manifold having a plurality of vapor collection inlets and a main vapor outlet, wherein at least one of the plurality of vapor collection inlets is fluidly coupled by a vapor line to the vapor outlet of a corresponding one of the one or more cooling devices.

2. The IT cooling system of claim 1, further comprising an auxiliary pump coupled in the liquid line between the liquid distribution manifold and the liquid inlet of at least one of the one or more cooling devices.

3. The IT cooling system of claim 2, further comprising at least one temperature sensor adapted to be coupled to the heat-generating component in one of the one or more servers, the at least one temperature sensor being communicatively coupled to a corresponding auxiliary pump.

4. The IT cooling system of claim 1, further comprising a main pump fluidly coupled to the main inlet of the liquid distribution manifold.

5. The IT cooling system of claim 4, further comprising a liquid sensor fluidly coupled in the vapor line between the vapor outlet of at least one of the one or more cooling devices and its corresponding vapor collection inlet, wherein the liquid sensor is communicatively coupled to the main pump.

6. The IT cooling system of claim 4, further comprising a circulation condenser external to the IT container, the circulation condenser being fluidly coupled to the main pump and the main vapor outlet of the vapor return manifold, so that the main pump circulates the two-phase circulation fluid through the liquid distribution manifold, the one or more cooling devices, the vapor return manifold, and the circulation condenser.

7. The IT cooling system of claim 1, further comprising an immersion condenser positioned above the immersion tank in the internal volume.

8. The IT cooling system of claim 1 wherein the two-phase immersion fluid and the two-phase circulation fluid are the same two-phase fluid.

9. The IT cooling system of claim 1, wherein the immersion tank comprises a tank inlet fluidly coupled to a source of the two-phase immersion fluid.

10. The IT cooling system of claim 9, wherein the tank inlet is fluidly coupled upstream of the main inlet of the liquid distribution manifold and includes a control valve fluidly coupled therein.

11. The IT cooling system of claim 10, further comprising a liquid level sensor positioned in the immersion tank, the liquid level sensor being communicatively coupled to the control valve to regulate the flow of two-phase immersion fluid into the tank.

12. The IT cooling system of claim 1, wherein the liquid inlet of each cooling device is disposed at or near the bottom of the cooling device and the vapor outlet of the cooling device is disposed at or near the top of the cooling device.

13. The IT cooling system of claim 1, wherein the two-phase circulation fluid circulates through the liquid distribution manifold, the one or more cooling devices, and the vapor return manifold.

14. The IT cooling system of claim 1, wherein the liquid distribution manifold comprises a main liquid inlet and one or more liquid distribution outlets, each of the liquid distribution outlets corresponding to one of the servers.

15. The IT cooling system of claim 14, wherein each of the liquid distribution outlets is fluidly coupled by a respective liquid line to the liquid inlet of each of the one or more cooling devices.

16. A cooling system for an information technology (IT) enclosure, the cooling system comprising:
an IT container defining an internal volume, the internal volume having therein:
an immersion tank adapted to submerge one or more servers in a two-phase immersion fluid,
one or more cooling devices, each cooling device designed to contain a volume of two-phase circulation fluid and adapted to be thermally coupled to a heat-generating component in one of the one or more servers and each cooling device including a liquid inlet and a vapor outlet,
a liquid distribution manifold positioned below the one or more cooling devices, the liquid distribution manifold fluidly coupled by a liquid line to the liquid inlet of each of the one or more cooling devices, and
a vapor return manifold positioned above the one or more cooling devices, the vapor return manifold having a plurality of vapor collection inlets and a main vapor outlet, wherein at least one of the plurality of vapor collection inlets is fluidly coupled by a vapor line to the vapor outlet of a corresponding one of the one or more cooling devices; and
a circulation condenser external to the IT container and fluidly coupled to the main vapor outlet of the vapor return manifold, wherein the two-phase circulation cooling fluid circulates through the liquid distribution manifold, the one or more cooling devices, the vapor return manifold, and the circulation condenser.

17. The IT cooling system of claim 16, further comprising an auxiliary pump coupled in the liquid line between the liquid distribution outlet and the liquid inlet of at least one of the one or more cooling devices.

18. The IT cooling system of claim 17, further comprising at least one temperature sensor adapted to be coupled to the heat-generating component in one of the one or more servers, the at least one temperature sensor being communicatively coupled to a corresponding auxiliary pump.

19. The IT cooling system of claim 16, further comprising a main pump fluidly coupled to the main inlet of the liquid distribution manifold.

20. The IT cooling system of claim 19, further comprising a liquid sensor fluidly coupled in the vapor line between the vapor outlet of at least one of the one or more cooling devices and its corresponding vapor collection inlet, wherein the liquid sensor is fluidly coupled to the main pump.
